(19) United States
(12) Patent Application Publication
(10) Pub. No.: US 2021/0292890 A1
(43) Pub. Date: Sep. 23, 2021

(54) EVAPORATION DEPOSITION DEVICE AND METHOD OF CONTROLLING SAME

(71) Applicant: Wuhan China Star Optoelectronics Semiconductor Display Technology Co., Ltd., Wuhan (CN)

(72) Inventor: Chao Xu, Wuhan (CN)

(21) Appl. No.: 16/323,521

(22) PCT Filed: Nov. 28, 2018
(86) PCT No.: PCT/CN2018/117834

§ 371 Date: Feb. 5, 2019

(30) Foreign Application Priority Data
Oct. 26, 2018 (CN) 201811260094.0

(51) Int. Cl. C23C 14/56; C23C 14/54; C23C 14/24

(52) U.S. Cl. CPC C23C 14/56; C23C 14/24; C23C 14/54

(57) ABSTRACT

An evaporation deposition device and a method of controlling same are provided. The evaporation deposition device includes a stage configured to carry a target substrate and an evaporation deposition component disposed opposite to the stage. The evaporation deposition component includes a first housing, a first switch configured to control opening or closing of the evaporation deposition component, an evaporation deposition source positioned in the first housing, and at least one recovery tank connected to the evaporation deposition source.

### FIELD OF INVENTION

The present disclosure relates to the field of display panel manufacturing technologies, and more particularly to an evaporation deposition device and a method of controlling same.

### BACKGROUND OF INVENTION

At present, one main way of manufacturing an organic light emitting diode (OLED) device is to heat an evaporation deposition coating. In the process, because the evaporation deposition coating is not a continuous evaporation deposition, it is necessary to turn off a switch of an evaporation deposition source after completing a coating of one substrate each time. An evaporation deposition device cannot be turned off, and the switch of the evaporation deposition source can only be turned on until a next substrate enters a chamber.

During a substrate switching process, evaporation deposition material is always consumed, and this wastes the evaporation deposition material and increases manufacturing cost of a display panel.

Therefore, there is a need for a new type of evaporation deposition device to solve the above issues.

### SUMMARY OF INVENTION

The present disclosure provides an evaporation deposition device and a method of controlling same to solve technical problems that a current display panel wastes raw materials in an evaporation deposition process.

To solve the above technical problems, a technical solution provided by the present disclosure is as follows:

An embodiment of the present disclosure provides an evaporation deposition device. The evaporation deposition device includes a stage configured to carry a target substrate and an evaporation deposition component disposed opposite to the stage. The evaporation deposition component includes a first housing, a first switch configured to control opening or closing of the evaporation deposition component, an evaporation deposition source positioned in the first housing, and at least one recovery tank connected to the evaporation deposition source.

In an embodiment of the present disclosure, the evaporation deposition source includes a second housing and a plurality of first through holes defined in the second housing.

In an embodiment of the present disclosure, the evaporation deposition source further includes at least one gas dispersion plate disposed in the second housing and a plurality of second through holes defined in the at least one gas dispersion plate.

In an embodiment of the present disclosure, a density of the second through holes in the at least one gas dispersion plate adjacent to the stage is not less than a density of the second through holes in the at least one gas dispersion plate away from the stage.

In an embodiment of the present disclosure, a bore diameter of each of the second through holes in the at least one gas dispersion plate adjacent to the stage is not less than a bore diameter of each of the second through holes in the at least one gas dispersion plate away from the stage.

In an embodiment of the present disclosure, the evaporation deposition component further includes a third switch disposed in the second housing, and the third switch covers the first through holes in the second housing.

In an embodiment of the present disclosure, the evaporation deposition source further includes a shutter plate disposed in the first through holes and a groove in which the shutter plate is placed.

In an embodiment of the present disclosure, the evaporation deposition component further includes at least one first passage, one end of the at least one first passage is connected to the at least one recovery tank, and another end of the at least one first passage is connected to the evaporation deposition source.

In an embodiment of the present disclosure, the evaporation deposition device further includes at least one second switch disposed in each of the at least one first passage.

In an embodiment of the present disclosure, each of the at least one recovery tank is connected to the at least one first passage.

An embodiment of the present disclosure further provides a method of controlling an evaporation deposition device. The evaporation deposition device includes a stage configured to carry a target substrate and an evaporation deposition component disposed opposite to the stage. The evaporation deposition component includes a first housing, a first switch configured to control opening or closing of the evaporation deposition component, an evaporation deposition source positioned in the first housing, and at least one recovery tank connected to the evaporation deposition source. The at least one recovery tank is connected to the evaporation deposition source through at least one first passage, and each of the at least one first passage is provided with at least one second switch. The method includes:

when the target substrate is subjected to an evaporation deposition process, the first switch is opened, and the at least one second switch is closed, and

when the target substrate completes the evaporation deposition process, the first switch is closed, the at least one second switch is opened, and the at least one recovery tank is used to recover an evaporation deposition material generated by the evaporation deposition source.

In an embodiment of the present disclosure, the evaporation deposition source includes a second housing and a plurality of first through holes defined in the second housing.

In an embodiment of the present disclosure, the evaporation deposition source further includes at least one gas dispersion plate disposed in the second housing and a plurality of second through holes defined in the at least one gas dispersion plate.

In an embodiment of the present disclosure, a density of the second through holes in the at least one gas dispersion plate adjacent to the stage is not less than a density of the second through holes in the at least one gas dispersion plate away from the stage.

In an embodiment of the present disclosure, a bore diameter of each of the second through holes in the at least one gas dispersion plate adjacent to the stage is not less than a bore diameter of each of the second through holes in the at least one gas dispersion plate away from the stage.

In an embodiment of the present disclosure, the evaporation deposition component further includes a third switch disposed in the second housing, and the third switch covers the first through holes in the second housing.

In an embodiment of the present disclosure, the evaporation deposition source further includes a shutter plate disposed in the first through holes and a groove in which the shutter plate is placed.

Beneficial effects of an embodiment of the present disclosure are that, the at least one recovery tank disposed in the evaporation deposition component is connected to the evaporation deposition source, such that evaporation deposition material can be collected by the at least one recovery tank during a substrate switching process, this reduces waste of materials and production costs.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a structural view of an evaporation deposition device according to a first embodiment of the present disclosure.

FIG. 2 is a top plan view of a first gas dispersion plate of an evaporation deposition device according to an embodiment of the present disclosure.

FIG. 3 is a top plan view of a second gas dispersion plate of an evaporation deposition device according to an embodiment of the present disclosure.

FIG. 4 is a structural view of an evaporation deposition device according to a second embodiment of the present disclosure.

FIG. 5 is a structural view of an evaporation deposition source of an evaporation deposition device according to a third embodiment of the present disclosure.

### DETAILED DESCRIPTION OF PREFERRED EMBODIMENTS

The following description of the various embodiments is provided to illustrate the specific embodiments. Directional terms described by the present disclosure, such as top, bottom, front, back, left, right, inner, outer, side, etc., are only directions by referring to the accompanying drawings, and thus the used terms are used only for the purpose of describing embodiments of the present disclosure and are not intended to be limiting of the present disclosure. In the drawings, units with similar structures are labeled with the same reference number.

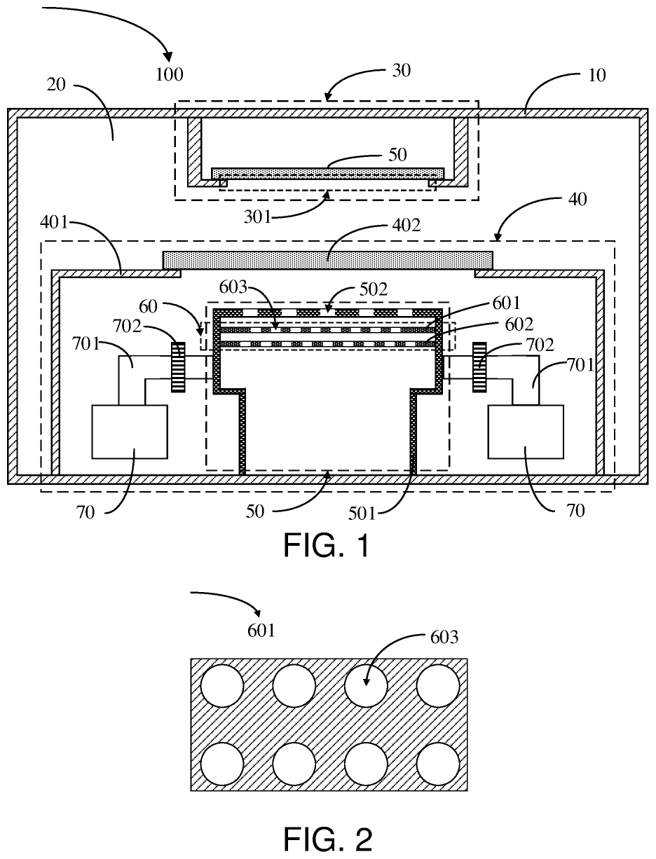

Referring to FIG. 1, a structural view of an evaporation deposition device according to a first embodiment of the present disclosure is provided.

The evaporation deposition device 100 includes a housing 10 and an evaporation deposition chamber 20 positioned in the housing 10. The evaporation deposition chamber 20 is provided with a stage 30 and an evaporation deposition component 40 disposed opposite to the stage 30.

The stage 30 is configured to carry a target substrate 50, and each of the target substrates 50 needs to be marked and aligned before evaporation deposition to reduce evaporation deposition errors.

In an embodiment, referring to FIG. 1, the stage 30 includes a first opening 301. In a horizontal direction, a pitch of the first opening 301 is less than a length of the substrate such that the substrate overlaps the stage 30. An area of the first opening 301 is a region where the target substrate 50 is configured to perform evaporation deposition.

In an embodiment, the stage may further include an adsorption device. The adsorption device fixes the target substrate by adsorption. Compared with the embodiment in which the first opening is formed, this embodiment increases an area of the target substrate for evaporation deposition, which reduces waste of materials.

The evaporation deposition component 40 includes a first housing 401 and a first switch 402 positioned on the first housing 401. The first switch 402 is a main switch of the evaporation deposition device 100 configured to control opening or closing of the evaporation deposition component 40. It can also be understood that the first switch 402 is configured to control stop and operation of the evaporation deposition process.

In an embodiment, the first switch 402 may be disposed in parallel with the first opening 301.

In an embodiment, an orthographic projection of the first opening 301 on the first switch 402 is positioned in the first switch 402.

In an embodiment, an area of the first opening 301 is less than an area of the first switch 402.

The evaporation deposition component 40 further includes an evaporation deposition source 50 positioned in the first housing 401. The evaporation deposition source 50 is configured to produce a desired evaporation deposition material in the evaporation deposition process.

In an embodiment, the evaporation deposition material can be an organic material, such as a luminescent material in an OLED device.

The evaporation deposition source 50 includes a second housing 501 and a first through hole 502 defined in the second housing 501 1. The first through hole 502 is configured to release the evaporation deposition material generated by the evaporation deposition source 50.

In an embodiment, the evaporation deposition source 50 may include a plurality of the first through holes 502. Arrangement, number, shape, and size of the first through holes 502 are not specifically limited and may be set according to actual needs.

In an embodiment, the first through holes 502 are distributed in an array on the first housing 401, and each of the first through holes 502 is equal in size and shape.

In an embodiment, the first through hole 502 may have a cylindrical shape.

The evaporation deposition source 50 further includes at least one gas dispersion plate 60 disposed in the second housing 501 and a second through hole 603 defined in the gas dispersion plate 60. The gas dispersion plate 60 is configured to uniformly release the evaporation deposition material generated by the evaporation deposition source 50, such that the target substrate 50 is ensured to have uniformity in evaporation coating.

In an embodiment, a density of the second through holes 603 in the gas dispersion plate 60 adjacent to the stage 30 is not less than a density of the second through holes 603 in the one gas dispersion plate 60 away from the stage 30.

In an embodiment, a bore diameter of the second through hole 603 in the gas dispersion plate 60 adjacent to the stage 30 is not less than a bore diameter of the second through hole 603 in the gas dispersion plate 60 away from the stage 30.

Referring to FIG. 1, the evaporation deposition source 50 includes a first gas dispersion plate 601 and a second gas dispersion plate 602. The first gas dispersion plate 601 is disposed adjacent to the first switch 402, and the second gas dispersion plate 602 is disposed away from the first switch 402. A plurality of the second through holes 603 are respectively defined in the first gas dispersion plate 601 and the second gas dispersion plate 602.

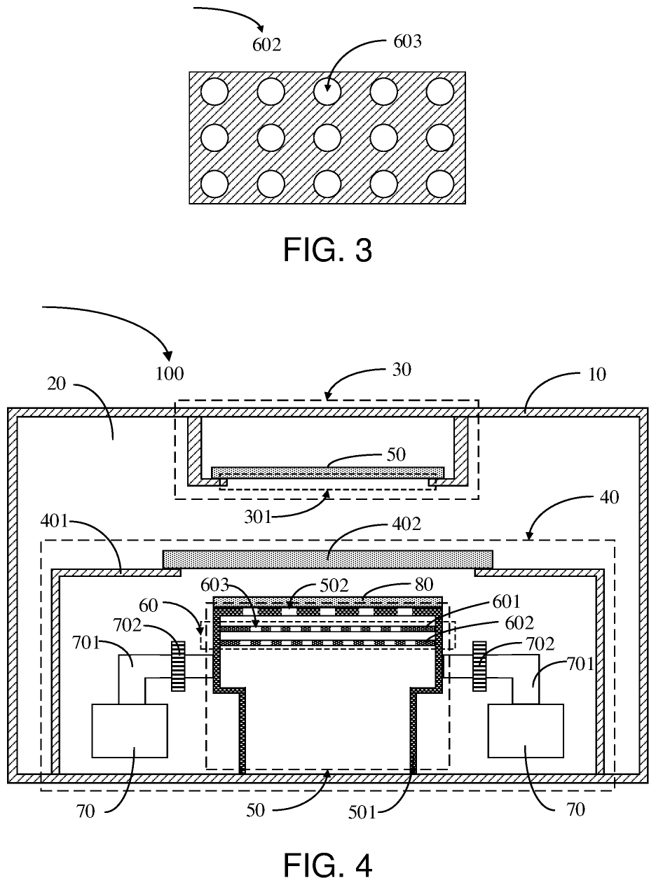

Refer to FIG. 2. FIG. 2 is a top plan view of the first gas dispersion plate of the evaporation deposition device according to an embodiment of the present disclosure. Refer to FIG. 3. FIG. 3 is a top plan view of the second gas dispersion plate of the evaporation deposition device according to an embodiment of the present disclosure.

In an embodiment, a density of the second through holes 603 in the first gas dispersion plate 601 is less than a density of the second through holes 603 in the second gas dispersion plate 602.

In an embodiment, a bore diameter of the second through hole 603 in the first gas dispersion plate 601 is greater than a bore diameter of the second through hole 603 in the second gas dispersion plate 602.

Referring to FIGS. 2 and 3, a shape of the second through hole 603 in the first gas dispersion plate 601 is same as a shape of the second through hole 603 in the second gas dispersion plate 602. The shape of the second through hole 603 in the first gas dispersion plate 601 and the shape of the second through hole 603 in the second gas dispersion plate 602 may be cylindrical.

The evaporation deposition source 50 further includes a heating device (not shown) disposed on a surface of the evaporation deposition source 50.

The heating device is configured to increase energy of the evaporation deposition material and increase an evaporation deposition rate of the evaporation deposition process. The heating device may also uniformly distribute the evaporation deposition material in the second housing 501.

In an embodiment, the heating device is a heating wire. The heating wire is uniformly distributed on the surface of the evaporation deposition source 50.

The evaporation deposition component 40 further includes at least one recovery tank 70 connected to the evaporation deposition source 50.

The evaporation deposition component 40 further includes at least one first passage 701, one end of the first passage 701 is connected to the recovery tank 70, and another end of the first passage 701 is connected to the evaporation deposition source 50. Each of the at least one first passages 701 is provided with at least one second switch 702.

Referring to FIG. 1, in an embodiment, the evaporation deposition component 40 includes two of the recovery tanks 70, and each of the recovery tanks 70 is connected to the evaporation deposition source 50 through one of the at least one first passage 701. The second switch 702 is disposed in each of the at least one first passage 701.

In an embodiment, the second switch 702 can be a solenoid valve.

In an embodiment, each of the recovery tanks 70 can be connected to the at least one first passages 701. By increasing a number of the first passages 701, the evaporation deposition material is recovered more rapidly.

A cooling device (not shown) is disposed in the recovery tank 70. The cooling device is configured to cooling the evaporation deposition material entering the recovery tank 70, and the recovery tank 70 forms a pressure difference with the evaporation deposition source 50 to increase a recovery rate.

When the target substrate 50 is subjected to an evaporation deposition process, first, the first switch 402 is in an open state, and the second switch 702 is in a closed state, such that the evaporation deposition material generated by the evaporation deposition source 50 enters a surface of the target substrate 50 from the first switch 402 to perform the evaporation deposition process. When the evaporation deposition process of the target substrate 50 is completed, substrate switching is performed. At this time, the first switch 402 is in a closed state, the second switch 702 is in an open state, and the evaporation deposition material generated by the evaporation deposition source 50 enters the recovery tank 70 through the first passage 701 to complete recovery of the evaporation deposition material, thereby reducing waste of the evaporation deposition material.

Refer to FIG. 4. FIG. 4 is a structural view of an evaporation deposition device according to a second embodiment of the present disclosure.

The evaporation deposition component 40 further includes a third switch 80 disposed in the second housing 501. The third switch 80 is disposed in parallel with a surface of the evaporation deposition source 50 to cover the first through hole 502 in the second housing 501.

When the target substrate 50 is subjected to an evaporation deposition process, the third switch 80 is in an open state, and the evaporation deposition material enters a surface of the target substrate 50 through the first through hole 502. When the target substrate 50 completes the evaporation deposition process, the third switch 80 is in a closed state, and the evaporation deposition material enters the recovery tank 70 through the first passage 701. This prevents the evaporation deposition material from entering the first housing 401 through the first through hole 502 and further reduces waste of the evaporation deposition material.

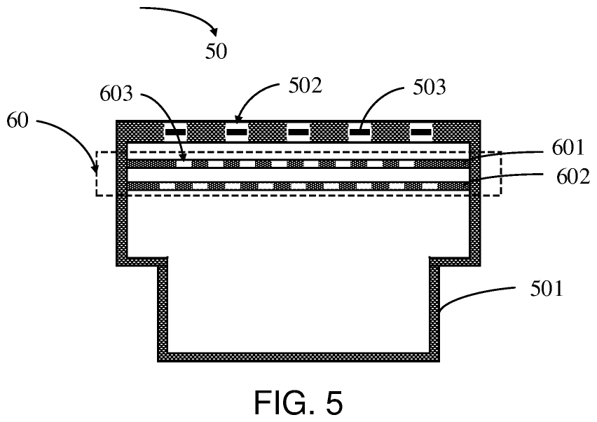

Refer to FIG. 5, FIG. 5 is a structural view of an evaporation deposition source of an evaporation deposition device according to a third embodiment of the present disclosure.

This embodiment is same as or similar to the second embodiment 2, differences therebetween are as follows:

The evaporation deposition source 50 includes a shutter plate 503 disposed in the first through hole 502 and a groove (not shown) in which the shutter plate 503 is placed.

When the target substrate 50 is subjected to an evaporation deposition process, the shutter plate 503 is placed in the groove 504 by a control device, such that the first through hole 502 is in an unobstructed state. When the target substrate 50 completes the evaporation deposition process, the shutter plate 503 is placed in the first through hole 502 by the control device, such that the first through hole 502 is in an occlusion state.

An embodiment of the present disclosure also provides a method of controlling the evaporation deposition device.

Referring to FIG. 1, the evaporation deposition device 100 includes a housing 10 and an evaporation deposition chamber 20 positioned in the housing 10. The evaporation deposition chamber 20 is provided with a stage 30 and an evaporation deposition component 40 disposed opposite to the stage 30.

The stage 30 is configured to carry a target substrate 50, and each of the target substrates 50 needs to be marked and aligned before evaporation deposition to reduce evaporation deposition errors.

In an embodiment, the stage 30 includes a first opening 301. In a horizontal direction, a pitch of the first opening 301 is less than a length of the substrate such that the substrate overlaps the stage 30. An area of the first opening 301 is a region where the target substrate 50 is configured to perform evaporation deposition.

In an embodiment, the stage may further include an adsorption device. The adsorption device fixes the target substrate by adsorption. Compared with the embodiment in which the first opening is formed, this embodiment increases an area of the target substrate for evaporation deposition, which reduces waste of materials.

The evaporation deposition component 40 includes a first housing 401 and a first switch 402 positioned on the first housing 401. The first switch 402 is a main switch of the evaporation deposition device 100 configured to control opening or closing of the evaporation deposition component 40. It can also be understood that the first switch 402 is configured to control stop and operation of the evaporation deposition process.

In an embodiment, the first switch 402 may be disposed in parallel with the first opening 301.

In an embodiment, an orthographic projection of the first opening 301 on the first switch 402 is positioned in the first switch 402.

In an embodiment, an area of the first opening 301 is less than an area of the first switch 402.

The evaporation deposition component 40 further includes an evaporation deposition source 50 positioned in the first housing 401. The evaporation deposition source 50 is configured to produce a desired evaporation deposition material in the evaporation deposition process.

In an embodiment, the evaporation deposition material can be an organic material, such as a luminescent material in an OLED device.

The evaporation deposition source 50 includes a second housing 501 and a first through hole 502 defined in the second housing 501 1. The first through hole 502 is configured to release the evaporation deposition material generated by the evaporation deposition source 50.

In an embodiment, the evaporation deposition source 50 may include a plurality of the first through holes 502. Arrangement, number, shape, and size of the first through holes 502 are not specifically limited and may be set according to actual needs.

In an embodiment, the first through holes 502 are distributed in an array on the first housing 401, and each of the first through holes 502 is equal in size and shape.

In an embodiment, the first through hole 502 may have a cylindrical shape.

The evaporation deposition source 50 further includes at least one gas dispersion plate 60 disposed in the second housing 501 and a second through hole 603 defined in the gas dispersion plate 60. The gas dispersion plate 60 is configured to uniformly release the evaporation deposition material generated by the evaporation deposition source 50, such that the target substrate 50 is ensured to have uniformity in evaporation coating.

In an embodiment, a density of the second through holes 603 in the gas dispersion plate 60 adjacent to the stage 30 is not less than a density of the second through holes 603 in the one gas dispersion plate 60 away from the stage 30.

In an embodiment, a bore diameter of the second through hole 603 in the gas dispersion plate 60 adjacent to the stage 30 is not less than a bore diameter of the second through hole 603 in the gas dispersion plate 60 away from the stage 30.

Referring to FIG. 1, the evaporation deposition source 50 includes a first gas dispersion plate 601 and a second gas dispersion plate 602. The first gas dispersion plate 601 is disposed adjacent to the first switch 402, and the second gas dispersion plate 602 is disposed away from the first switch 402. A plurality of the second through holes 603 are respectively defined in the first gas dispersion plate 601 and the second gas dispersion plate 602.

Refer to FIGS. 2 and 3, a density of the second through holes 603 in the first gas dispersion plate 601 is less than a density of the second through holes 603 in the second gas dispersion plate 602.

In an embodiment, a bore diameter of the second through hole 603 in the first gas dispersion plate 601 is greater than a bore diameter of the second through hole 603 in the second gas dispersion plate 602.

Referring to FIGS. 2 and 3, a shape of the second through hole 603 in the first gas dispersion plate 601 is same as a shape of the second through hole 603 in the second gas dispersion plate 602. The shape of the second through hole 603 in the first gas dispersion plate 601 and the shape of the second through hole 603 in the second gas dispersion plate 602 may be cylindrical.

The evaporation deposition source 50 further includes a heating device (not shown) disposed on a surface of the evaporation deposition source 50.

The heating device is configured to increase energy of the evaporation deposition material and increase an evaporation deposition rate of the evaporation deposition process. The heating device may also uniformly distribute the evaporation deposition material in the second housing 501.

In an embodiment, the heating device is a heating wire. The heating wire is uniformly distributed on the surface of the evaporation deposition source 50.

The evaporation deposition component 40 further includes at least one recovery tank 70 connected to the evaporation deposition source 50.

The evaporation deposition component 40 further includes at least one first passage 701, one end of the first passage 701 is connected to the recovery tank 70, and another end of the first passage 701 is connected to the evaporation deposition source 50. Each of the at least one first passages 701 is provided with at least one second switch 702.

Referring to FIG. 1, in an embodiment, the evaporation deposition component 40 includes two of the recovery tanks 70, and each of the recovery tanks 70 is connected to the evaporation deposition source 50 through one of the at least one first passage 701. The second switch 702 is disposed in each of the at least one first passage 701.

In an embodiment, the second switch 702 can be a solenoid valve.

In an embodiment, each of the recovery tanks 70 can be connected to the at least one first passages 701. By increasing a number of the first passages 701, the evaporation deposition material is recovered more rapidly.

A cooling device (not shown) is disposed in the recovery tank 70. The cooling device is configured to cooling the evaporation deposition material entering the recovery tank 70, and the recovery tank 70 forms a pressure difference with the evaporation deposition source 50 to increase a recovery rate.

When the target substrate 50 is subjected to an evaporation deposition process, first, the first switch 402 is in an open state, and the second switch 702 is in a closed state, such that the evaporation deposition material generated by the evaporation deposition source 50 enters a surface of the target substrate 50 from the first switch 402 to perform the evaporation deposition process. When the evaporation deposition process of the target substrate 50 is completed, substrate switching is performed. At this time, the first switch 402 is in a closed state, the second switch 702 is in an open state, and the evaporation deposition material generated by the evaporation deposition source 50 enters the recovery tank 70 through the first passage 701 to complete a recovery of the evaporation deposition material, thereby reducing waste of the evaporation deposition material.

Referring to FIG. 4, the evaporation deposition component 40 further includes a third switch 80 disposed in the second housing 501. The third switch 80 is disposed in parallel with a surface of the evaporation deposition source 50 to cover the first through hole 502 in the second housing 501.

When the target substrate 50 is subjected to an evaporation deposition process, the third switch 80 is in an open state, and the evaporation deposition material enters a surface of the target substrate 50 through the first through hole 502. When the target substrate 50 completes the evaporation deposition process, the third switch 80 is in a closed state, and the evaporation deposition material enters the recovery tank 70 through the first passage 701. This prevents the evaporation deposition material from entering the first housing 401 through the first through hole 502 and further reduces waste of the evaporation deposition material.

Referring to FIG. 5, this embodiment is same as or similar to the second embodiment 2, differences therebetween are as follows:

The evaporation deposition source 50 includes a shutter plate 503 disposed in the first through hole 502 and a groove (not shown) in which the shutter plate 503 is placed.

When the target substrate 50 is subjected to an evaporation deposition process, the shutter plate 503 is placed in the groove 504 by a control device, such that the first through hole 502 is in an unobstructed state. When the target substrate 50 completes the evaporation deposition process, the shutter plate 503 is placed in the first through hole 502 by the control device, such that the first through hole 502 is in an occlusion state.

An embodiment of the present disclosure provides an evaporation deposition device and a method of controlling the evaporation deposition device. The evaporation deposition device includes a stage configured to carry a target substrate and an evaporation deposition component disposed opposite to the stage. The evaporation deposition component includes a first housing, a first switch configured to control opening or closing of the evaporation deposition component, an evaporation deposition source positioned in the first housing, and at least one recovery tank connected to the evaporation deposition source. The at least one recovery tank disposed in the evaporation deposition component is connected to the evaporation deposition source, such that evaporation deposition material can be collected by the at least one recovery tank during a substrate switching process, this reduces waste of materials and production costs.

Although the present disclosure is described via one or more embodiments, those of ordinary skill in the art can come up with equivalent variations and modifications based upon the understanding of the specification and the accompanying drawings. The present disclosure includes all such modifications and variations and is only limited by the scope of the appended claims. In particular, as to the various functions performed by the components described above, the terms used to describe the components are intended to correspond to any component performing the specific functions (e.g., which are functionally equivalent) of the components (unless otherwise indicated), even those which are structurally different from the disclosed structure for performing the functions in the exemplary embodiments in the specification shown herein. In addition, although a particular feature in the specification is disclosed in only one of many embodiments, this feature may be combined with one or more features in other embodiments which are desirable and advantageous to a given or particular application. Moreover, the terms “include”, “have”, “consist of”, or variations thereof used in the detailed description or the claims are intended to be used in a manner similar to the term “comprising”.

In summary, although the preferable embodiments of the present disclosure have been disclosed above. It should be noted that those of ordinary skill in the art can make a variety of improvements and substitutions on the premise of not deviating from the technical principle of the present disclosure, and these improvements and substitutions should be encompassed within the protection scope of the present disclosure.

What is claimed is:

1. An evaporation deposition device, comprising:
a stage configured to carry a target substrate; and
an evaporation deposition component disposed opposite to the stage, the evaporation deposition component comprising:
a first housing;
a first switch configured to control opening or closing of the evaporation deposition component;
an evaporation deposition source positioned in the first housing; and
at least one recovery tank connected to the evaporation deposition source.

2. The evaporation deposition device according to claim 1, wherein the evaporation deposition source comprises a second housing and a plurality of first through holes defined in the second housing.

3. The evaporation deposition device according to claim 2, wherein the evaporation deposition source further comprises at least one gas dispersion plate disposed in the second housing and a plurality of second through holes defined in the at least one gas dispersion plate.

4. The evaporation deposition device according to claim 3, wherein a density of the second through holes in the at least one gas dispersion plate adjacent to the stage is not less than a density of the second through holes in the at least one gas dispersion plate away from the stage.

5. The evaporation deposition device according to claim 3, wherein a bore diameter of each of the second through holes in the at least one gas dispersion plate adjacent to the stage is not less than a bore diameter of each of the second through holes in the at least one gas dispersion plate away from the stage.

6. The evaporation deposition device according to claim 2, wherein the evaporation deposition component further comprises a third switch disposed in the second housing, and the third switch covers the first through holes in the second housing.

7. The evaporation deposition device according to claim 2, wherein the evaporation deposition source further comprises a shutter plate disposed in the first through holes and a groove in which the shutter plate is placed.

8. The evaporation deposition device according to claim 1, wherein the evaporation deposition component further comprises at least one first passage, one end of the at least one first passage is connected to the at least one recovery tank, and another end of the at least one first passage is connected to the evaporation deposition source.

9. The evaporation deposition device according to claim 8, further comprising at least one second switch disposed in each of the at least one first passage.

10. The evaporation deposition device according to claim 8, wherein each of the at least one recovery tank is connected to the at least one first passage.

11. A method of controlling an evaporation deposition device, wherein the evaporation deposition device comprises a stage configured to carry a target substrate and an evaporation deposition component disposed opposite to the stage, wherein the evaporation deposition component comprising:
a first housing;
a first switch configured to control opening or closing of the evaporation deposition component;
an evaporation deposition source positioned in the first housing; and
at least one recovery tank connected to the evaporation deposition source, wherein the at least one recovery tank is connected to the evaporation deposition source through at least one first passage, and each of the at least one first passage is provided with at least one second switch;
wherein the method comprises:
when the target substrate is subjected to an evaporation deposition process, the first switch is opened, and the at least one second switch is closed;
when the target substrate completes the evaporation deposition process, the first switch is closed, the at least one second switch is opened, and the at least one recovery tank is used to recover an evaporation deposition material generated by the evaporation deposition source.

12. The method according to claim 11, wherein the evaporation deposition source comprises a second housing and a plurality of first through holes defined in the second housing.

13. The method according to claim 12, wherein the evaporation deposition source further comprises at least one gas dispersion plate disposed in the second housing and a plurality of second through holes defined in the at least one gas dispersion plate.

14. The method according to claim 13, wherein a density of the second through holes in the at least one gas dispersion plate adjacent to the stage is not less than a density of the second through holes in the at least one gas dispersion plate away from the stage.

15. The method according to claim 13, wherein a bore diameter of each of the second through holes in the at least one gas dispersion plate adjacent to the stage is not less than a bore diameter of each of the second through holes in the at least one gas dispersion plate away from the stage.

16. The method according to claim 12, wherein the evaporation deposition component further comprises a third switch disposed in the second housing, and the third switch covers the first through holes in the second housing.

17. The method according to claim 12, wherein the evaporation deposition source further comprises a shutter plate disposed in the first through holes and a groove in which the shutter plate is placed.
